(19) United States
(12) Patent Application Publication
(10) Pub. No.: US 2024/0208442 A1
(43) Pub. Date: Jun. 27, 2024

(54) POWER DISTRIBUTION UNIT WITH PLANAR BUSBARS

(71) Applicant: Dana Heavy Vehicle Systems Group, LLC, Maumee, OH (US)

(72) Inventors: Sylvain CASTONGUAY, Laval (CA); Martin HOULE, Laval (CA)

(21) Appl. No.: 18/526,604

(22) Filed: Dec. 1, 2023

Related U.S. Application Data
(60) Provisional application No. 63/476,775, filed on Dec. 22, 2022.

(51) Int. Cl. B60R 16/023; B60R 16/03; H05K 1/02; H05K 7/02; H05K 7/06

(52) U.S. Cl. CPC B60R 16/0238; B60R 16/03; H05K 1/0263; H05K 7/026; H05K 7/06; H05K 2201/10272

(57) ABSTRACT

A system is provided for a power distribution unit with planar busbars. The system includes an interface piece with a plurality of mounting surfaces, a group of electrical components mounted on the interface piece such that each electrical component is positioned within the same plane, and a planar electrical busbar that has a top surface positioned entirely in one plane and that is electrically coupled to one or more of the electrical components.

### CROSS-REFERENCE TO RELATED APPLICATIONS

This application claims priority to U.S. Provisional Application No. 63/476,775, entitled “POWER DISTRIBUTION UNIT WITH PLANAR BUSBARS,” and filed Dec. 22, 2022, the entire contents of which is hereby incorporated by reference for all purposes.

### TECHNICAL FIELD

The present disclosure relates to a power distribution unit including planar busbars. The power distribution unit may be used to distribute power in an electrical system such as an electric vehicle.

### BACKGROUND AND SUMMARY

Busbars may be used in power distribution systems to transmit current where a wiring scheme is infeasible. A busbar is a conductive material distributing electric power from a supply point to numerous output circuits. Used in a variety of configurations, busbars can come in a multitude of shapes and sizes such as solid bars, flat strips, or rods, and are commonly composed of copper, aluminum, or brass. Their cross-sectional size and material composition determine the amount of current that can be carried by the busbar.

Busbars may be used in power distribution units (PDUs), also referred to as junction boxes or circuit boxes, to facilitate current transmission among electrical components of the PDUs. For example, a busbar may electrically connect a power source, such as a traction battery, to a plurality of electrical loads (e.g., pump, HVAC, inverters) via electrical components such as fuses, contactors, and the like. The electrical components may be housed in a housing of the PDU, such as coupled to a base of the housing.

However, the inventors herein have recognized some issues with the use of busbars to electrically couple components in a PDU. The electrical components of the PDU may vary in height and may be positioned along the base of the PDU housing. As a result, the busbars in the PDU may be bent in multiple axes (and thereby extend in more than one plane) to facilitate coupling of the electrical input port(s) of the PDU to the electrical components of the PDU. These multi-plane/bent busbars may increase the cost and complexity of the PDU and may limit opportunities for pre-assembling aspects of the PDU, which may further increase manufacturing costs and time.

Thus, the inventors herein have developed a power distribution unit to at least partly address the above-described issues. In one example, a power distribution unit includes an interface piece having a plurality of mounting surfaces, a first group of electrical components, each electrical component of the first group of electrical components including a first connector, each electrical component of the first group of electrical components positioned on a respective mounting surface of the plurality of mounting surfaces such that each first connector is arranged in a same plane; and a planar electrical busbar with a top surface extending entirely in one plane, the planar electrical busbar including one or more external connection portions, wherein each of the one or more external connection portions are electrically coupled to one of the first connectors of the first group of electrical components. In this way, planar busbars may be used, where the busbars extend substantially in only one plane. Planar busbars may be less costly to manufacture. Further, the interface piece that brings the connectors of the electrical components to the same plane as the planar busbar may improve manufacturing efficiency by allowing pre-assembly of the electrical components, the interface piece, and the busbar(s), which may then collectively be installed in a PDU housing. Additionally, the interface piece may act as an electrical insulator for the electrical components, which may alleviate the need for additional, separate insulators, further lowering manufacturing cost and complexity.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The accompanying drawings are incorporated herein as part of the specification. The drawings described herein illustrate embodiments of the presently disclosed subject matter, and are illustrative of selected principles and teachings of the present disclosure. However, the drawings do not illustrate all possible implementations of the presently disclosed subject matter, and are not intended to limit the scope of the present disclosure in any way.

FIG. 1A shows a perspective view of a power distribution unit (PDU);

FIG. 1B shows a perspective view of the PDU of FIG. 1A without one sidewall and a housing base;

FIG. 2A shows a side view of the PDU of FIG. 1A without a sidewall;

FIG. 2B shows a top perspective view of the PDU of FIG. 2A without a housing cover;

FIG. 3 shows an exploded perspective view of the PDU of FIG. 1A;

FIG. 4A shows a top view of a PDU pre-assembly;

FIG. 4B shows a top perspective view of the PDU pre-assembly of FIG. 4A;

FIG. 5 shows an exploded view of the PDU pre-assembly of FIG. 4A;

FIG. 6 shows an electrical circuit diagram of an electric vehicle including PDUs; and

FIG. 7 shows a method for assembling a PDU.

### DETAILED DESCRIPTION

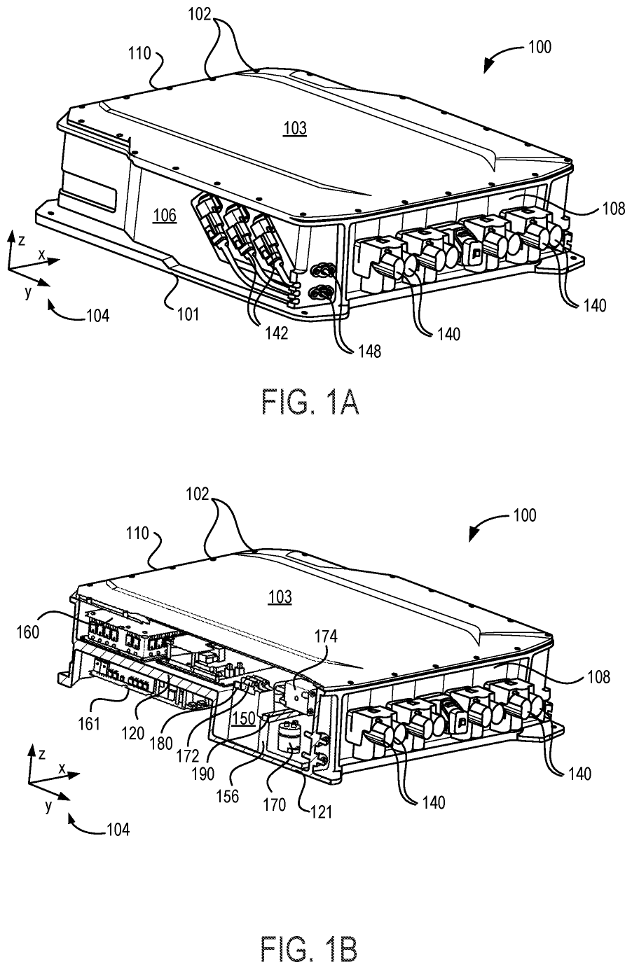

The following description relates to systems and methods for organizing a power distribution unit (PDU), also referred to as an electrical junction box. FIGS. 1A-5 are shown to scale, though other relative dimensions may be used. FIGS. 1A-5 include a Cartesian coordinate system 104 to orient the views. The z-axis of coordinate system 104 may be a vertical axis (e.g., parallel to a gravitational axis), the y-axis of coordinate system 104 may be a longitudinal axis (e.g., horizontal axis), and/or the x-axis of coordinate system 104 may be a lateral axis, in one example. However, the axes may have other orientations, in other examples. When referencing direction, positive may refer to in the direction of the arrow of the x-axis, y-axis, and z-axis and negative may refer to in the opposite direction of the arrow of the x-axis, y-axis, and z-axis. A filled circle may represent an arrow and axis facing toward, or positive to, a view. An unfilled circle may represent an arrow and an axis facing away, or negative to, a view.

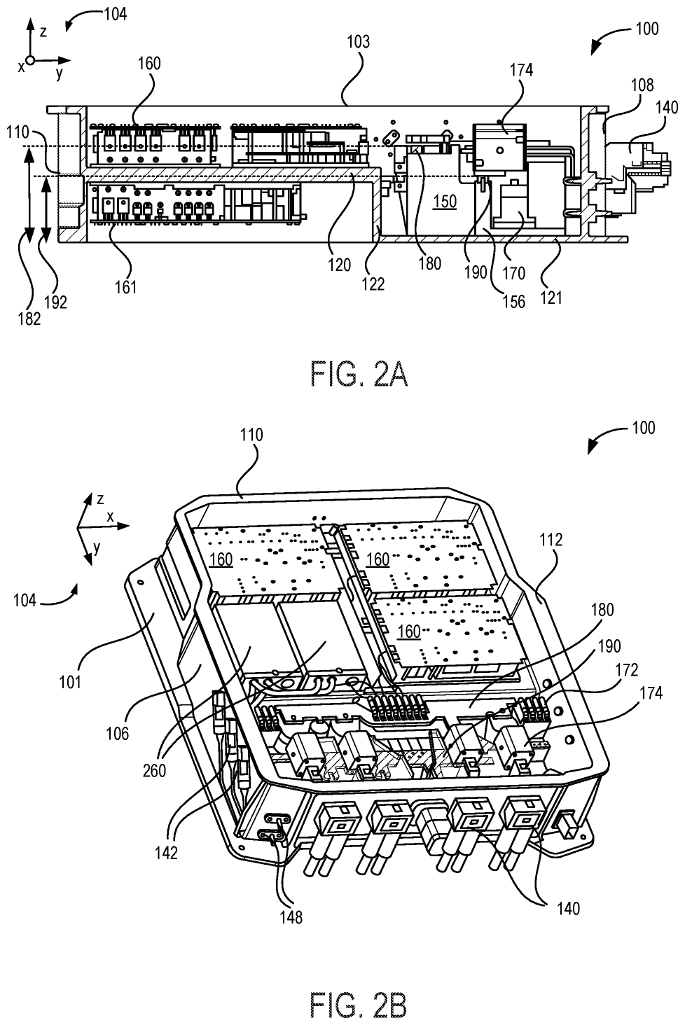

FIGS. 1A, 1B, 2A, and 2B show an example PDU 100 and will be described collectively. The PDU 100 may include a housing base 101, a housing cover 103, housing side walls (e.g., a housing side wall 106 and housing side wall 112 opposite housing side wall 106), and housing end walls (e.g., a housing end wall 108 and housing end wall 110 opposite housing end wall 108). The housing side wall 106 is removed in FIGS. 1B and 2A to allow visualization of features within the PDU 100. The housing cover 103 is removed in FIG. 2B for visualization of features within the PDU 100. The housing base 101 may be comprised of bottom surfaces of the housing side walls and housing end walls as well as a housing bottom portion 121 (e.g., shown in FIG. 1B). The longitudinal axis of the housing cover 103 may be parallel to the y-axis, the lateral axis of the housing cover 103 may be parallel to the x-axis, and the vertical axis of the housing cover 103 may be parallel to the z-axis. The housing cover 103 may be positioned higher than the housing base 101, relative to the z-axis.

The housing side walls, including the housing side wall 106 and the housing side wall 112 (shown in FIG. 2B), may each have a longitudinal axis that is parallel to the y-axis, a lateral axis that is parallel to the z-axis, and a vertical axis that is parallel to the x-axis. The housing end walls, including the housing end wall 108 and the housing end wall 110, may each have a longitudinal axis that is parallel to the x-axis, a lateral axis that is parallel to the z-axis, and a vertical axis that is parallel to the y-axis. The housing side walls and the housing end walls may each be orthogonal to the housing base 101 and the housing cover 103 and may each be positioned between the housing base 101 and the housing cover 103, relative to the z-axis. As such, the housing base 101, the housing cover 103, the housing side walls, and the housing end walls may at least partially form (e.g., at least partially encase) an interior volume of the PDU 100. The top edge, relative to the z-axis, of each of the housing side walls and housing end walls may be coupled to the housing cover 103 via a plurality of fasteners 102. At least portions of the housing side walls and/or housing end walls may include flanges that extend outward in an x-y plane, which form part of the housing base 101, and which include through-holes or other mechanisms to allow mounting of the PDU 100 to a suitable structure.

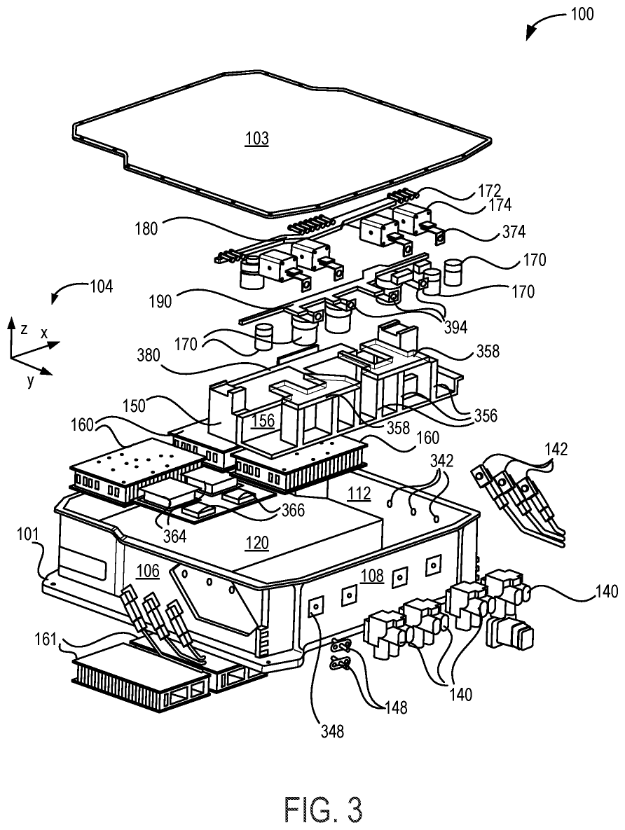

A plurality of electrical connectors 140 may be coupled to the external surface of the housing end wall 108. Additionally, a plurality of first external connectors 142 and a plurality of second external connectors 148 may be coupled to the housing side wall 106. At least one first external connector of the plurality of first external connectors 142 may be coupled to the housing side wall 112, as illustrated in FIG. 3.

As shown in FIGS. 1B and 2A, the housing of the PDU 100 may include a housing raised base portion 120 positioned within the PDU 100. The housing raised base portion 120 may extend from the housing end wall 110 to the center of the PDU 100 with respect to the y-axis. As shown in FIG. 3, the housing raised base portion 120 may also extend from the housing side wall 106 to the housing side wall 112 with respect to the x-axis. The housing raised base portion 120 may have a top surface that is flat and parallel with the x-y plane, as well as be positioned at a height that is approximately 50% of the height of the PDU 100, with respect to the z-axis. Thus, the housing raised base portion 120 may include an elevated platform that is positioned above the bottom of the PDU 100, and the housing of the PDU 100 may further include a connecting side wall 122 that extends vertically from the housing raised base portion 120 to the housing bottom portion 121. The housing bottom portion 121 may extend from the raised base portion 120 to the housing end wall 108, and from the housing side wall 106 to the housing side wall 112.

A plurality of PCBs (printed circuit boards) may be positioned both above and below the housing raised base portion 120, with respect to the z-axis. As shown in FIGS. 2A and 2B, the plurality of PCBs may be coupled to the housing raised base portion 120, with the plurality of PCBs including a first plurality of PCBs 160 (e.g., three PCBs) coupled to a top surface of the housing raised base portion 120 (and thus positioned above the housing raised base portion 120) and a second plurality of PCBs 161 coupled to a bottom surface of the housing raised base portion 120 (and thus positioned below the housing raised base portion 120). The plurality of PCBs may be used to control various electrical features of the PDU 100, such as main circuitry. The housing raised base portion 120 may also be coupled to a plurality of component housings 260. The plurality of component housings 260 may be positioned on top of the housing raised base portion 120, relative to the z-axis. In some examples, as illustrated in FIG. 3, there may be one or more electrical components, such as a plurality of electrical components 364 and a plurality of electrical components 366, coupled to the housing raised base portion 120 and housed by the plurality of component housings 260.

Also illustrated in FIGS. 1B, 2A, and 2B are a plurality of first electrical components 170, a plurality of resistors 172, and a plurality of second electrical components 174. The plurality of first electrical components 170 may be a plurality of power devices, fuses, contactors, and/or other suitable electrical components. Similarly, the plurality of second electrical components 174 may be a plurality of power devices, fuses, contactors, and/or other suitable electrical components.

The plurality of resistors 172 and the plurality of second electrical components 174 may be positioned on top of an interface piece 150, with respect to the z-axis. The interface piece 150 may extend vertically upward from the housing bottom portion 121 and may be coupled to the housing bottom portion 121 along a bottom of the interface piece 150. In some examples, the interface piece 150 may be made of an insulating material (e.g., a non-conductive material), such as plastic, and formed outside of the housing of the PDU 100. As such, the interface piece 150 may serve as an insulating component interposed between electrical components of the PDU 100 and the housing of the PDU 100. The interface piece 150 may be created through injection molding, or a similar process. In other examples, the interface piece 150 may be made of aluminum (similar to the housing base 101) and integrally formed with the housing base 101. As such, insulating elements may be interposed between electrical components of the PDU 100 and the interface piece 150 as needed. As illustrated in FIGS. 3-5, the interface piece 150 may comprise a plurality of riser elements such as riser element 156. The plurality of second electrical components 174 may be positioned above the riser element 156, relative to the z-axis and a portion of the plurality of first electrical components 170 may be coupled to a base 502 of the interface piece 150.

A plurality of mounting surfaces of the interface piece 150 may be in face sharing contact with a first planar electrical busbar 180 and a second planar electrical busbar 190. In FIG. 2B, the second planar electrical busbar 190 is shaded with a diagonal line pattern. As shown in FIG. 2A, the top surface of the first planar electrical busbar 180 may be positioned at a first height 182 and the top surface of the second planar electrical busbar 190 may be positioned at a second height 192, where the first height 182 is taller than the second height 192, with respect to the z-axis. The entire top surface of the first planar electrical busbar 180 may be positioned at the first height 182, and may therefore be entirely within a two-dimensional plane which is parallel to the x-y plane. Similarly, the entire top surface of the second planar electrical busbar 190 may be positioned at the second height 192, and may therefore be entirely within a two-dimensional plane which is parallel to the x-y plane. The top surface of the first planar electrical busbar 180 may be within a different plane than the top surface of the second planar electrical busbar 190.

FIG. 3 shows an exploded perspective view of the PDU 100. The housing side wall 106 and the housing side wall 112 may each include a plurality of housing ports 342. The plurality of housing ports 342 may allow the plurality of first external connectors 142 to connect to various components within the housing of the PDU 100. Similarly, the housing end wall 108 may include a plurality of housing ports, such as housing port 348. The plurality of housing ports, including housing port 348, may allow the electrical connectors 140 to connect to various components within the housing of the PDU 100, such as a plurality of first electrical connectors 374 and/or a plurality of second electrical connectors 394. The plurality of first electrical connectors 374 may be coupled to a plurality of electrical components, such as the plurality of second electrical components 174.

In turn, the plurality of electrical components, such as the plurality of second electrical components 174, may be coupled to the first planar electrical busbar 180 (whether directly or indirectly via a respective first electrical component). Similarly, the plurality of second electrical connectors 394 may be coupled to a plurality of electrical components, such as the plurality of first electrical components 170. In turn, the plurality of electrical components, such as the plurality of first electrical components 170, may be coupled to the second planar electrical busbar 190.

As shown in FIG. 3, the plurality of riser elements of the interface piece 150 may include a plurality of further riser elements 356 in addition to the riser element 156. The plurality of further riser elements 356 may be taller than the riser element 156, with respect to the z-axis. The plurality of further riser elements 356 may support a plurality of platforms 358. A portion of the bottom surface of each platform in the plurality of platforms 358 may be in face sharing contact with the top edge of at least one riser element of the plurality of further riser elements 356. The top surfaces of the plurality of platforms 358 may all be flat and positioned at the same height relative to the z-axis. The plurality of platforms 358 may be in face sharing contact with one or more electrical connectors of the plurality of first electrical connectors 374. One or more of the sides (e.g., the surfaces orthogonal to the top surface) of the plurality of platforms 358 may be in face sharing contact with one or more surfaces of each of the electrical components in the plurality of second electrical components 174. Additionally, each platform in the plurality of platforms 358 may be an insulating element providing insulation between the plurality of first electrical connectors 374, the plurality of second electrical connectors 394, and various additional electric components within the housing of the PDU 100.

Each electrical connector in the plurality of first electrical connectors 374 may be positioned at a same height relative to the z-axis (e.g., the top surface of each electrical connector of the plurality of first electrical connectors 374 may be in a 2D plane). Similarly, each electrical connector in the plurality of second electrical connectors 394 may be positioned at a same height relative to the z-axis (e.g., the top surface of each electrical connector of the plurality of second electrical connectors 394 may be in a 2D plane).

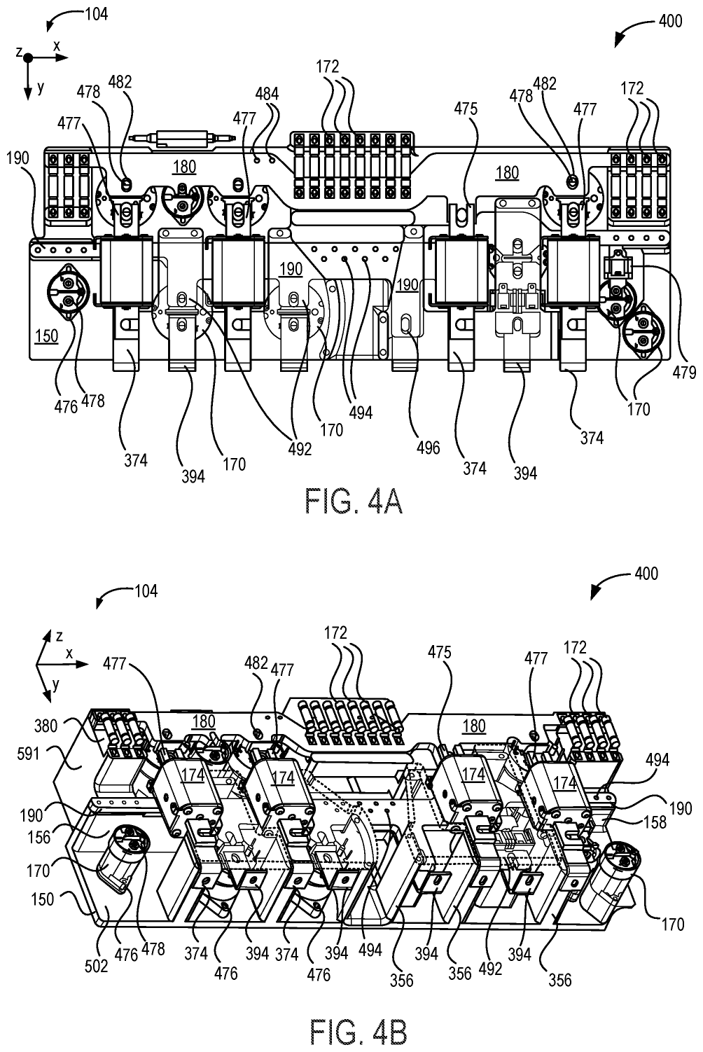

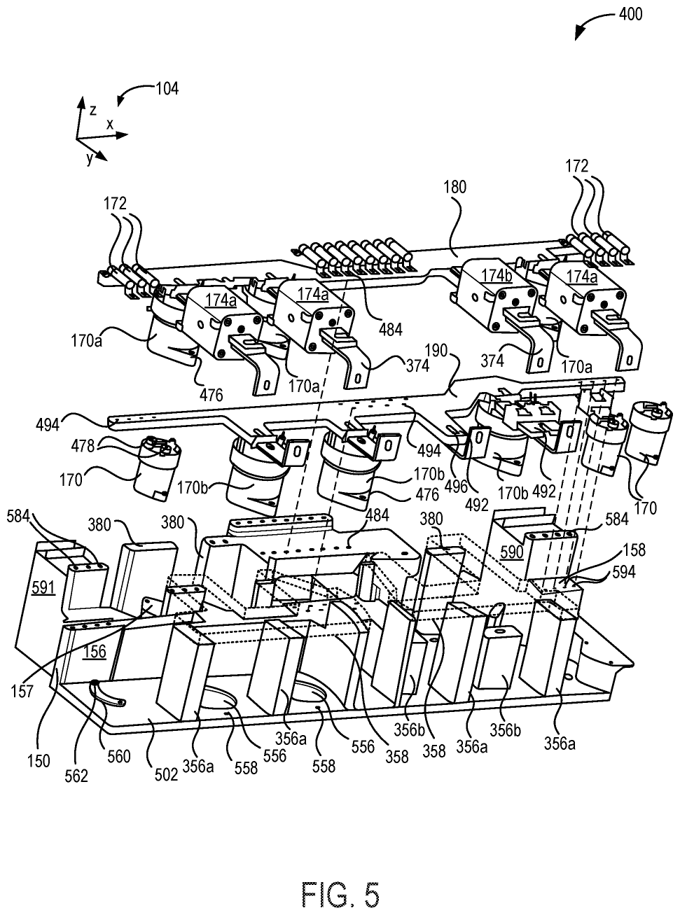

The interface piece 150 may include one or more additional riser elements 380 in addition to the riser element 156 and the plurality of further riser elements 356. The one or more additional riser elements 380 may have the same height as the plurality of further riser elements 356, with respect to the z-axis. At least a portion of the top surface of the one or more additional riser elements 380 may be in face sharing contact with at least a portion of the first planar electrical busbar 180, and may in part support the first planar electrical busbar 180 against the force of gravity. Additionally, the one or more additional riser elements 380 may provide insulation between the first planar electrical busbar 180 and various additional electrical components within the housing of the PDU 100. Similarly, at least a portion of the top surface of the riser element 156 and riser element 158 (visible in FIGS. 4B and 5) may be in face-sharing contact with at least a portion of the second planar electrical busbar 190, and may in part support the second planar electrical busbar 190 against the force of gravity. Additionally, the riser element 156 and riser element 158 may provide insulation between the second planar electrical busbar 190 and various additional electrical components within the housing of the PDU 100.

FIGS. 4A and 4B show an example PDU pre-assembly 400 and will be described collectively. The PDU pre-assembly 400 may be assembled outside of the housing of a PDU (e.g., PDU 100 of FIGS. 1-3), before being inserted into the housing. For example, the PDU pre-assembly 400 may be assembled and then inserted into the housing to form the PDU 100. The PDU pre-assembly may include a first busbar pre-assembly and a second busbar pre-assembly, where the assembled first busbar pre-assembly and the assembled second busbar pre-assembly may each be mounted into a housing of a PDU. As such, assembling a PDU that utilizes a PDU pre-assembly, such as the PDU pre-assembly 400, may be easier and quicker than assembling a PDU that does not utilize a PDU pre-assembly.

The first planar electrical busbar 180 may have a plurality of connector holes 482 that extend through the first planar electrical busbar 180 in the direction of the z-axis. The plurality of connector holes 482 may accommodate a plurality of electrical connectors 478, which may facilitate an electrical connection between the first planar electrical busbar 180 and one or more of the plurality of first electrical components 170. In this way, each electrical connector of the one or more of the plurality of first electrical components 170 may remain in the same two-dimensional (2D) plane that is parallel to the x-y plane. The first planar electrical busbar 180 may also be electrically connected to each electrical component of the plurality of second electrical components 174 through a first connector 475 and a plurality of second connectors 477. The first connector 475 may be in face sharing contact with the top surface of the first planar electrical busbar 180, and may therefore be positioned at a height higher than the first height 182, relative to the z-axis. The second connectors 477 may be in the same 2D plane as the first planar electrical busbar 180 (e.g., positioned at the first height 182), and may be electrically coupled to the first planar electrical busbar 180 through additional electrical components, such as the one or more of the plurality of first electrical components 170.

Similarly, the second planar electrical busbar 190 may have a plurality of connector holes 496 that extend through the second planar electrical busbar 190 in the direction of the z-axis. The plurality of connector holes 496 may accommodate electrical connectors and facilitate and electrical connection between the second planar electrical busbar 190 and various electrical components within the PDU pre-assembly 400 (e.g., one or more of the plurality of first electrical components 170). The plurality of connector holes 496 may be located on one or more of a plurality of planar busbar branches 492. The plurality of planar busbar branches 492 may extend from the second planar electrical busbar 190 while remaining in the same 2D plane as the second planar electrical busbar 190 (e.g., positioned at the second height 192, relative to the z-axis). The plurality of planar busbar branches 492 may allow for electrical connections between the second planar electrical busbar 190 and additional electrical components within the PDU pre-assembly 400 that may not be aligned with the second planar electrical busbar 190 in the z-direction.

The first planar electrical busbar 180 may include a plurality of mounting holes 484. The plurality of mounting holes 484 may be utilized in mounting the first planar electrical busbar 180 onto the interface piece 150 via a plurality of fasteners or other suitable mounting hardware. Similarly, the second planar electrical busbar 190 may include a plurality of mounting holes 494. The plurality of mounting holes 494 may be utilized in mounting the second planar electrical busbar 190 onto the interface piece 150 via a plurality of fasteners or other suitable mounting hardware.

Each first electrical component 170 may include a respective mounting base bracket 476 positioned at the bottom of the first electrical component 170. Each of the mounting base brackets 476 may be used to couple one of the first electrical components of the plurality of first electrical components 170 to the interface piece 150. The PDU pre-assembly 400 may also include one or more bracket connectors 479. The one or more bracket connectors 479 may create an electrical connection between the second planar electrical busbar 190 and one or more first electrical components of the plurality of first electrical components 170.

FIG. 5 shows an exploded perspective view of the PDU pre-assembly 400. The interface piece 150 may include a first end riser element 590 which is similar (e.g., in height) to the one or more additional riser elements 380. The first end riser element 590 may have the same height as the plurality of further riser elements 356, with respect to the z-axis. At least a portion of the top surface of the first end riser element 590 may be in face sharing contact with at least a portion of the first planar electrical busbar 180, and may in part support the first planar electrical busbar 180 against the force of gravity. Additionally, the first end riser element 590 may provide insulation between the first planar electrical busbar 180 and various additional electrical components of the PDU pre-assembly 400. The interface piece 150 may include a second end riser element 591 that is similar to the first end riser element 590 but located on the opposite end of the interface piece 150.

The first end riser element 590 and the second end riser element 591 may each include a plurality of riser mounting holes 584. The plurality of riser mounting holes 584 may provide a place to mount the plurality of resistors 172. The plurality of resistors 172 may be coupled to the plurality of riser mounting holes 584 via fasteners or other suitable mounting hardware. Similarly, the interface piece 150 may have a plurality of riser mounting holes 594 positioned at the second height 192. The plurality of riser mounting holes 594 may align with at least a subset of the mounting holes 494 that are positioned on the second planar electrical busbar 190. In this way, the second planar electrical busbar 190 may be coupled to the interface piece 150 via fasteners or other suitable mounting hardware that may extend through both the plurality of mounting holes 494 and the plurality of riser mounting holes 594.

The interface piece 150 may include a plurality of mounting wells 556 and a plurality of mounting holes 558. The plurality of mounting wells 556 may be utilized for positioning and mounting a portion of the plurality of first electrical components 170 onto the base of the interface piece 150. The plurality of mounting wells 556 may each have a depth such that each of the top surfaces of the portion of the plurality of first electrical components 170 may be at the second height 192. The plurality of mounting holes 558 may be positioned such that the plurality of mounting base brackets 476 may be coupled to the interface piece 150 via fasteners or other suitable mounting hardware that may extend through the plurality of mounting base brackets 476 and into the plurality of mounting holes 558. Additionally, the base of the interface piece 150 may include a mounting bracket 560. The mounting bracket 560 may include a plurality of mounting holes 562 which may be used to couple at least one electric component to the base of the interface piece 150.

FIG. 5 also illustrates the arrangement of different subsets of the plurality of first electrical components 170 and the plurality of second electrical components 174. For example, the plurality of first electrical components 170 includes a first portion of first electrical components each electrically coupled to the first busbar 180 (shown as first electrical components 170a). Each first electrical component 170a includes an electrical connector, such as electrical connector 478 (FIG. 5 shows the first electrical components 170a coupled to the first busbar 180 and thus the electrical connectors are not visible). Further, the plurality of first electrical components 170 includes a second portion of first electrical components each electrically coupled to the second busbar 190 (shown as first electrical components 170b). Each first electrical component 170b includes an electrical connector, such as electrical connector 478 (FIG. 5 shows the first electrical components 170b coupled to the second busbar 190 and thus the electrical connectors are not visible). In a non-limiting example, each first electrical component is a contactor. Furthermore, the plurality of second electrical components 174 includes a first portion of second electrical components (shown as second electrical components 174a) each coupled to a respective first electrical component 170a and a second electrical component 174b coupled to the first busbar 180. Each second electrical component 174a includes two electrical connectors: a first connector, such as second connector 477, that couples the second electrical component 174a to a respective first electrical component 170a and a second connector, such as first electrical connector 374, that couples the second electrical component 174a to a connector of the plurality of electrical connectors 140. In a non-limiting example, each second electrical component is a fuse.

Thus, FIG. 5 shows an assembly for a power distribution unit (PDU) that includes a first busbar (e.g., first busbar 180) having a first top surface extending entirely in a first plane and a first bottom surface extending entirely in a second plane, a plurality of first electrical components (e.g., first electrical components 170a) each having a first electrical connector (e.g., electrical connectors 478), a plurality of second electrical components (e.g., second electrical components 174a) each having a second electrical connector (e.g., second connectors 477), and an interface piece (e.g., interface piece 150) including a first portion supporting the first busbar, a second portion supporting the plurality of first electrical components, and a third portion supporting the plurality of second electrical components. The first portion may include the first end riser element 590, the second end riser element 591, and the one or more additional riser elements 380. The second portion may include platforms 157 (only one of which is visible in FIG. 5). The third portion may include one or more further riser elements 356 (e.g., a subset of the further riser elements 356). For example, in FIG. 5, the further riser elements that are positioned to support the plurality of second electrical components (and thus make up the third portion) are shown as further riser elements 356a. The further riser elements 356 may also include further riser elements 356b that are positioned to support the second busbar 190, and specifically contact/support respective branches of the second busbar 190 that are directly coupled to respective second electrical connectors 394. The second portion maintains each first electrical connector of the plurality of first electrical components at the same first vertical position relative to the first busbar, and the third portion maintains each second electrical connector of the plurality of second electrical components at the same second vertical position relative to first busbar. The first electrical connectors of the plurality of first electrical components are electrically coupled to the first busbar and each first electrical component is positioned vertically below the first busbar. Each second electrical component (e.g., second electrical component 174a) may be electrically coupled to a respective first electrical component (e.g., first electrical component 170a). Additionally, each second electrical component includes a respective third electrical connector (first electrical connectors 374), and the third portion of the interface piece includes a plurality of columns (e.g., each further riser element 356 may be a column) extending vertically upward from a base of the interface piece (e.g., base 502), each column supporting a respective third electrical connector.

The assembly may further include a second busbar (e.g., second planar electrical busbar 190) having a second top surface extending entirely in a third plane and a second bottom surface extending entirely in a fourth plane and a plurality of third electrical components (e.g., first electrical components 170b) each having a third electrical connector (e.g., electrical connectors 478). The interface piece includes a fourth portion (e.g., riser element 156 and riser element 158) supporting the second busbar and the base of the interface piece supports the plurality of third electrical components, such that the base maintains each third connector of the plurality of third electrical components at the same third vertical position relative to the second busbar. Each third electrical connector (e.g., the electrical connectors 478 of the first electrical components 170b) may be electrically coupled to the second busbar and each third electrical component (the first electrical components 170b) may be positioned vertically below the second busbar.

The second busbar may be located at a first height relative to the base of the interface piece and the first busbar may be located at a second height relative to the base of the interface piece, the second height larger than the first height. The assembly is configured to be housed in a housing of a PDU. The interface piece may be comprised of plastic or another suitable insulating material.

In some examples, as shown, the first electrical components 170a may each have a longitudinal axis that extends vertically (e.g., parallel to the z axis) and each first electrical connector (e.g., the electrical connectors 478 of the first electrical components 170a) may be positioned on a top of a respective first electrical component, which may facilitate electrical coupling to the first busbar at the bottom surface of the first busbar. Each second electrical component 174a may have a longitudinal axis that extends horizontally (e.g., parallel to the y axis). The second electrical connectors (e.g., second connectors 477) may extend along the y axis from the second electrical component to the first busbar and couple to the top of a respective first electrical component 170a. The third electrical connectors (e.g., first electrical connectors 374) may also extend along the y axis on an opposite side of the second electrical component. Each third electrical connector may be in face-sharing contact with a respective column/further riser element 356, or in face-sharing contact with a top surface of a platform 358. Similarly, the third electrical components (e.g., the first electrical components 170b) may have a longitudinal axis that extends vertically (e.g., parallel to the z axis) and each electrical connector of the third electrical components (e.g., the electrical connectors 478 of the first electrical components 170b) may be positioned on a top of a respective third electrical component, which may facilitate electrical coupling to the second busbar at the bottom surface of the second busbar.

In this way, the interface piece may include different portions having different heights relative to a base of the interface piece to maintain the various electrical components at specified positions relative to the two busbars so that the busbars may couple to the electrical components without the busbars having any segments that extend along the z axis (other than the thickness of the busbars, which may extend between the respective top and bottom surfaces and may be uniform across the busbars).

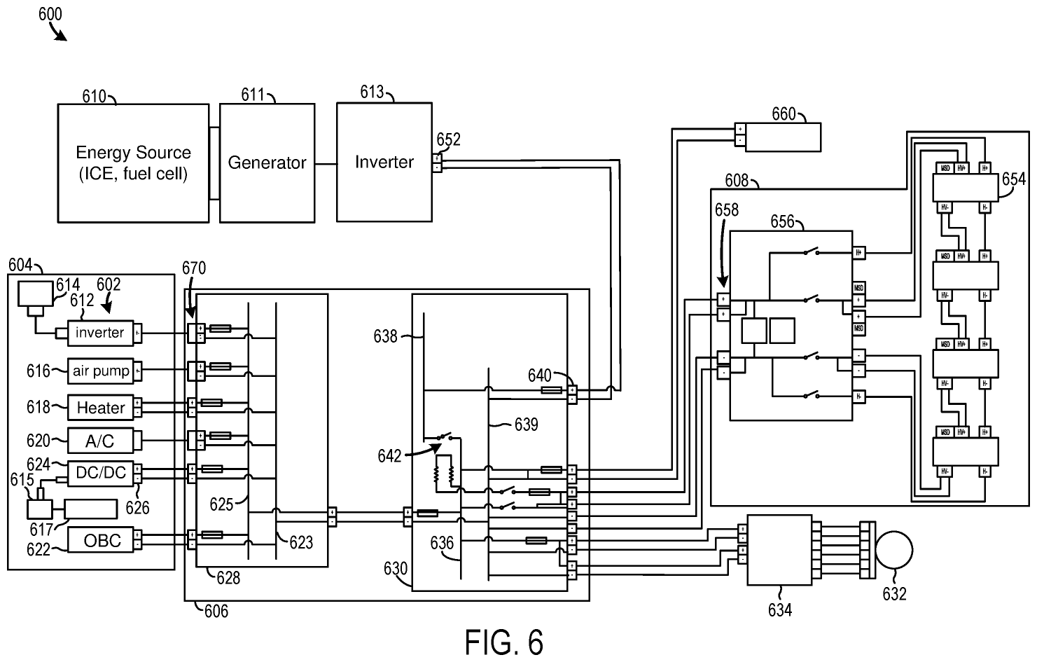

FIG. 6 shows a circuit diagram of an example vehicle system 600 that includes one or more power distribution units for distributing electrical power from an energy source (e.g., a vehicle battery system). One or more PDUs included in vehicle system 600 may be configured similarly to the PDU 100 of FIGS. 1A-5, as will be explained in more detail below (e.g., vehicle system 600 may include PDU 100). It will be appreciated that the circuit diagram serves as an example of circuitry in an electric vehicle (EV) system. Thus, vehicle system 600 includes a motor 634 to deliver mechanical power to drive wheels of the vehicle system 600 (not shown). A transmission, gearbox, and/or other suitable powertrain components may be used to accomplish this power transfer functionality. The motor 634 may be an alternating current (AC) motor that receives power from an inverter 632.

The vehicle system 600 may include electric accessories 602 in an accessory assembly 604, an electric distribution assembly 606 that includes one or more PDUs (e.g., PDU 100), a traction battery assembly 608, and, in some examples, an alternate energy source 610. The alternate energy source 610 may include an internal combustion engine (ICE), a hydrogen fuel cell assembly, or another energy source. When the alternate energy source 610 includes an ICE, the vehicle system 600 may further include a generator 611 coupled to the ICE and configured to convert rotational energy from the ICE to electrical energy, as well as an inverter 613 coupled to the generator 611.

The traction battery assembly 608 may include one or more batteries and/or other suitable energy storage devices such as capacitors. The traction battery assembly 608 may further include a heater and contactors that allow the individual battery packs to be heated and selectively disconnected. The batteries in the traction battery assembly 608 as well as the other batteries described herein may be constructed with a number of suitable chemistries. For instance, the batteries may include lithium ion batteries, lithium ion polymer batteries, nickel-metal hydride batteries, lithium air batteries, combination thereof, and the like. In the illustrated example, the traction battery assembly 608 includes multiple power packs 654 (e.g., batteries). The power packs may be coupled in parallel and/or series. Further, a distribution box 656 or other suitable electrical arrangement may serve as an electrical interface between ports 658 of the traction battery assembly 608 and the power packs 654. The traction battery assembly 608 may supply electric energy to the electric accessories 602 and the motor 634 via the electric distribution assembly 606.

The electric accessories 602 may include a power-steering inverter 612 coupled to a power-steering pump 614, an air pump 616, a cabin heater 618, a cabin air conditioning (AC) unit 620, an on board charger 622, a DC-DC converter 624, and/or the like. The DC-DC converter 624 may be coupled to a low voltage (LV) battery 615, which can power LV accessories 617 such as an infotainment system. Each of the accessories includes electrical ports 626 that enable connection between the accessories and a first PDU 628 (e.g., a first high voltage distribution box) included in the electric distribution assembly 606. The electric distribution assembly 606 may further include a second PDU 630 (e.g., a second high voltage distribution box). In some examples, the PDUs may distribute approximately 24 volts to the components which are electrically coupled thereto. However, other operating voltages have been contemplated.

Each of the first PDU 628 and the second PDU 630 may include one or more buses to enable electronic communication and distribution of power from an energy source to one or more electrical loads. The buses may be busbars in some examples. For example, the first PDU 628 includes a first busbar 625 and a second busbar 623. The second PDU 630 may include a first busbar 636 and a second busbar 639 (as well as a third busbar 638). The first busbar 625 may be electrically coupled to the first busbar 636. The second busbar 623 may be electrically coupled to the second busbar 639. While two separate PDUs are depicted in FIG. 6, it is to be appreciated that the two PDUs could be combined into a single PDU, with the first busbar 636 and first busbar 625 forming one first busbar and the second busbar 623 and second busbar 639 forming one second busbar.

The first PDU 628 is electrically coupled to the traction battery assembly 608 and the motor 634 and inverter 632 via the second PDU 630 (e.g., via respective electrical couplings between the first busbars of the PDUs and the second busbars of the PDUs). The first PDU 628 is electrically coupled to the electric accessories 602 via ports 670 on the first PDU 628 and respective electrical ports 626 on each accessory. The inverter 613 is electrically coupled to the second busbar 639 and to the third busbar 638. Each of these connections may be established via ports 640 in the second PDU.

An alternate energy source contactor 642 may be positioned between the third busbar 638 and the first busbar 636 to allow the traction battery assembly 608 and motor 634 to be selectively electrically isolated from the inverter 613. The inverter 613 may be electrically coupled to the second PDU 630 via ports 652.

The A battery chiller 660 may further be included in the traction battery assembly 608 or more generally in the vehicle system 600. The battery chiller 660 may be electrically coupled to the second PDU 630. The battery chiller 660 is designed to reduce the temperature of the battery packs.

The PDU(s) within electric distribution assembly 606 may be configured as described above with respect to FIGS. 1A-5. For example, the first busbar 625 may be a planar busbar with a single, continuous top surface, where an entirety of the top surface extends in one plane. The components of the PDU that are coupled to the first busbar 625 may be positioned on an interface piece so that the connectors of the components (which physically couple to the first busbar 625) may be arranged in the same plane. The first busbar 625 may be a non-limiting example of the first planar electrical busbar 180 of FIG. 5. Similarly, the second busbar 623 may be a planar busbar, and may be a non-limiting example of the second planar electrical busbar 190 of FIG. 5. The PDU 628 may be a non-limiting example of the PDU 100.

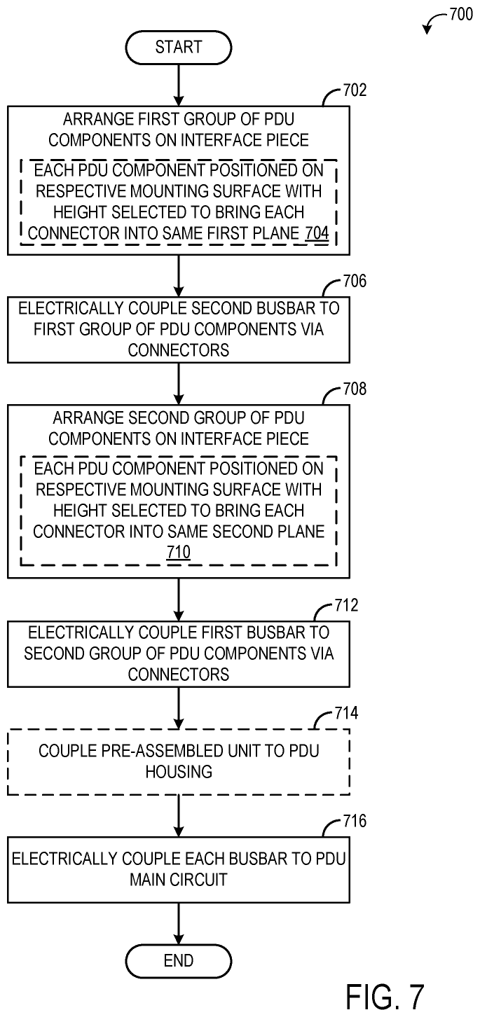

FIG. 7 is a flow chart illustrating a method 700 for assembling a PDU according to an embodiment of the present disclosure. In some examples, PDU 100 of FIGS. 1A-5 may be assembled according to method 700.

At 702, method 700 includes arranging a first group of PDU components on an interface piece. The first group of PDU components may include electrical components (e.g., contactors, fuses) of the PDU, such as the plurality of first electrical components 170b of FIG. 5, configured to couple to a second busbar of the PDU (e.g., second busbar 190). Each PDU component of the first group of PDU components may include a respective connector, such as one of the electrical connectors of the electrical connectors 478, configured to electrically couple to the second busbar. The interface piece may include a mounting surface for each PDU component (e.g., mounting wells 556 in base 502), and each PDU component of the first group of PDU components may be positioned on a respective mounting surface of the interface piece, with the height of each mounting surface selected to bring each connector of the first group of PDU components into a same, first plane, as indicated at 704.

At 706, method 700 includes electrically coupling the second busbar to the first group of PDU components via the connectors of the first group of PDU components. For example, the second busbar may include external connection portions and each connector of the first group of PDU components may be electrically coupled to a respective external connection portion of the second busbar. In doing so, the external connection portions of the second busbar may be positioned in the same first plane as the connectors or in a plane immediately adjacent the first plane (e.g., above or below).

At 708, method 700 includes arranging a second group of PDU components on the interface piece. The second group of PDU components may include electrical components (e.g., contactors, fuses) of the PDU, such as the first electrical components 170a and the plurality of second electrical components 174a of FIG. 5, configured to couple to a first busbar of the PDU (e.g., first busbar 180). Each PDU component of the second group of PDU components may include a respective connector, such as one of the electrical connectors of the second connectors 477 and electrical connectors 478, configured to electrically couple to the first busbar or another electrical component. Each PDU component of the second group of PDU components may be positioned on a respective mounting surface of the interface piece, with the height of each mounting surface selected to bring each connector of the second group of PDU components into a same, second plane, as indicated at 710. For example, each of the first electrical components 170a may be positioned on a platform of platforms 157 and each of the second electrical components 174a may be positioned on a further riser element 356a.

At 712, method 700 includes electrically coupling the first busbar to the second group of PDU components via the connectors of the second group of PDU components. For example, the first busbar may include external connection portions and each connector of the first electrical components 170a of the second group of PDU components may be electrically coupled to a respective external connection portion of the second busbar. In doing so, the external connection portions of the second busbar may be positioned in the same second plane as the connectors or in a plane immediately adjacent the first plane (e.g., above or below). Each connector of the second electrical components 174a may be coupled to a respective first electrical component 170a. It is to be appreciated that in some examples, the connectors of the first electrical components 170a may be in the same plane as the connectors of the second electrical components 174a, or they may be in slightly different but adjacent planes (e.g., within 1-3 mm).

At 714, method 700 optionally includes coupling a pre-assembled interface unit to a housing of the PDU. The pre-assembled interface unit may include the first and second groups of PDU components positioned on the interface piece and the first and second busbars coupled to the first and second groups of PDU components. The interface piece may be secured to the PDU housing, such as secured to a base of the PDU housing. However, in other examples, the interface piece may be formed integrally with the PDU housing, and the first and second groups of PDU components may be positioned on the interface piece when the interface piece is already in the PDU housing. In such examples, when the first and second groups of PDU components are positioned on the interface piece, a respective insulating component may be positioned between each PDU component and the interface piece. Once the pre-assembled interface unit is positioned in the housing of the PDU, the first and second groups of PDU components may be coupled to ports on the housing, such as the plurality of housing ports 342 and/or the plurality of housing ports 348 of FIG. 3.

At 716, method 700 includes electrically coupling each busbar to a PDU main circuit. For example, the first busbar may be coupled to one or more printed circuit boards (PCBs), one or more PDU controllers, and/or other suitable electrical components within the housing of the PDU. Similarly, the second busbar may be coupled to one or more PCBs, one or more PDU controllers, and/or other suitable electrical components within the housing of the PDU. In some examples, the first busbar and the second busbar may each be coupled to the same PCBs, PDU controllers and/or other suitable electrical components. In other examples, the first busbar and the second busbar may be coupled to one or more different PCBs, PDU controllers, and/or other suitable electrical components.

The disclosure also provides support for a power distribution unit (PDU), comprising: an interface piece having a plurality of mounting surfaces, a first group of electrical components, each electrical component of the first group of electrical components including a first connector, each electrical component of the first group of electrical components positioned on a respective mounting surface of the plurality of mounting surfaces such that each first connector is arranged in a same plane, and a planar electrical busbar with a top surface extending entirely in one plane, the planar electrical busbar including one or more external connection portions, wherein each of the one or more external connection portions are electrically coupled to one of the first connectors of the first group of electrical components. In a first example of the system, the interface piece is comprised of a non-conductive material. In a second example of the system, optionally including the first example, the first group of electrical components comprises one or more of fuses and contactors. In a third example of the system, optionally including one or both of the first and second examples, the system further comprises: a housing, wherein the interface piece is coupled to a base of the housing. In a fourth example of the system, optionally including one or more or each of the first through third examples, the interface piece is formed integrally with the base of the housing. In a fifth example of the system, optionally including one or more or each of the first through fourth examples, the plurality of mounting surfaces is a plurality of first mounting surfaces, and further comprising a second group of electrical components, each electrical component of the second group of electrical components including a second connector, each electrical component of the second group of electrical components positioned on a respective mounting surface of a plurality of second mounting surfaces of the interface piece such that each second connector is arranged in another same plane that is different than the plane of the first group of electrical connectors.

The disclosure also provides support for a method of assembling a power distribution unit (PDU), comprising: assembling a first busbar pre-assembly, including, for each of a plurality of electrical components, each of the electrical components including an electrical connector: arranging each electrical connector in a same two-dimensional (2D) plane, coupling each electrical connector to a planar electrical busbar, and mounting the assembled first busbar pre-assembly into a housing of the PDU. In a first example of the method, the method further comprises: assembling a second busbar pre-assembly and mounting the assembled second busbar pre-assembly into the housing of the PDU. In a second example of the method, optionally including the first example for each of the plurality of electrical components, arranging the electrical connector in a 2D plane includes mounting the electrical connector on a riser to elevate the electrical connector to the 2D plane. In a third example of the method, optionally including one or both of the first and second examples, mounting the assembled first busbar pre-assembly into the housing includes insulating each of the electrical components from the housing of the PDU. In a fourth example of the method, optionally including one or more or each of the first through third examples, insulating each of the electrical components from the housing of the PDU includes coupling a respective insulating element between the housing of the PDU and each electrical component.

The disclosure also provides support for an assembly for a power distribution unit (PDU), comprising: a first busbar having a first top surface extending entirely in a first plane and a first bottom surface extending entirely in a second plane, a plurality of first electrical components each having a first electrical connector, a plurality of second electrical components each having a second electrical connector, an interface piece including a first portion supporting the first busbar, a second portion supporting the plurality of first electrical components, and a third portion supporting the plurality of second electrical components, wherein: the second portion maintains each first electrical connector of the plurality of first electrical components at the same first vertical position relative to the first busbar, and the third portion maintains each second electrical connector of the plurality of second electrical components at the same second vertical position relative to first busbar. In a first example of the system, each first electrical connector is electrically coupled to the first busbar and each first electrical component is positioned vertically below the first busbar. In a second example of the system, optionally including the first example, each second electrical component is electrically coupled to a respective first electrical component. In a third example of the system, optionally including one or both of the first and second examples, each second electrical component includes a respective third electrical connector, and wherein the third portion of the interface piece includes a plurality of columns extending vertically upward from a base of the interface piece, each column supporting a respective third electrical connector. In a fourth example of the system, optionally including one or more or each of the first through third examples, the system further comprises: a second busbar having a second top surface extending entirely in a third plane and a second bottom surface extending entirely in a fourth plane and a plurality of third electrical components each having a third electrical connector, and wherein the interface piece includes a fourth portion supporting the second busbar and a base supporting the plurality of third electrical components, wherein the base maintains each third connector of the plurality of third electrical components at the same third vertical position relative to the second busbar. In a fifth example of the system, optionally including one or more or each of the first through fourth examples, each third electrical connector is electrically coupled to the second busbar and each third electrical component is positioned vertically below the second busbar. In a sixth example of the system, optionally including one or more or each of the first through fifth examples, the second busbar is located at a first height relative to the base of the interface piece and the first busbar is located at a second height relative to the base of the interface piece, the second height larger than the first height. In a seventh example of the system, optionally including one or more or each of the first through sixth examples, the assembly is configured to be housed in a housing of the PDU. In an eighth example of the system, optionally including one or more or each of the first through seventh examples, the interface piece is comprised of plastic.

It will be appreciated that the configurations and routines disclosed herein are exemplary in nature, and that these specific examples are not to be considered in a limiting sense, because numerous variations are possible. For example, the above technology can be applied to powertrains that include different types of propulsion sources including different types of electric machines and transmissions. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A power distribution unit (PDU), comprising:
an interface piece having a plurality of mounting surfaces;
a first group of electrical components, each electrical component of the first group of electrical components including a first connector, each electrical component of the first group of electrical components positioned on a respective mounting surface of the plurality of mounting surfaces such that each first connector is arranged in a same plane; and
a planar electrical busbar with a top surface extending entirely in one plane, the planar electrical busbar including one or more external connection portions, wherein each of the one or more external connection portions are electrically coupled to one of the first connectors of the first group of electrical components.

2. The PDU of claim 1, wherein the interface piece is comprised of a non-conductive material.

3. The PDU of claim 1, wherein the first group of electrical components comprises one or more of fuses and contactors.

4. The PDU of claim 1, further comprising a housing, wherein the interface piece is coupled to a base of the housing.

5. The PDU of claim 4, wherein the interface piece is formed integrally with the base of the housing.

6. The PDU of claim 1, wherein the plurality of mounting surfaces is a plurality of first mounting surfaces, and further comprising a second group of electrical components, each electrical component of the second group of electrical components including a second connector, each electrical component of the second group of electrical components positioned on a respective mounting surface of a plurality of second mounting surfaces of the interface piece such that each second connector is arranged in another same plane that is different than the plane of the first group of electrical connectors.

7. A method of assembling a power distribution unit (PDU), comprising:
assembling a first busbar pre-assembly, including, for each of a plurality of electrical components, each of the electrical components including an electrical connector:
arranging each electrical connector in a same two-dimensional (2D) plane;
coupling each electrical connector to a planar electrical busbar; and
mounting the assembled first busbar pre-assembly into a housing of the PDU.

8. The method of claim 7, further comprising assembling a second busbar pre-assembly and mounting the assembled second busbar pre-assembly into the housing of the PDU.

9. The method of claim 7, wherein, for each of the plurality of electrical components, arranging the electrical connector in a 2D plane includes mounting the electrical connector on a riser to elevate the electrical connector to the 2D plane.

10. The method of claim 9, wherein mounting the assembled first busbar pre-assembly into the housing includes insulating each of the electrical components from the housing of the PDU.

11. The method of claim 10, wherein insulating each of the electrical components from the housing of the PDU includes coupling a respective insulating element between the housing of the PDU and each electrical component.

12. An assembly for a power distribution unit (PDU), comprising:
a first busbar having a first top surface extending entirely in a first plane and a first bottom surface extending entirely in a second plane;
a plurality of first electrical components each having a first electrical connector;
a plurality of second electrical components each having a second electrical connector;
an interface piece including a first portion supporting the first busbar, a second portion supporting the plurality of first electrical components, and a third portion supporting the plurality of second electrical components, wherein:
the second portion maintains each first electrical connector of the plurality of first electrical components at the same first vertical position relative to the first busbar; and
the third portion maintains each second electrical connector of the plurality of second electrical components at the same second vertical position relative to first busbar.

13. The assembly of claim 12, wherein each first electrical connector is electrically coupled to the first busbar and each first electrical component is positioned vertically below the first busbar.

14. The assembly of claim 13, wherein each second electrical component is electrically coupled to a respective first electrical component.

15. The assembly of claim 12, wherein each second electrical component includes a respective third electrical connector, and wherein the third portion of the interface piece includes a plurality of columns extending vertically upward from a base of the interface piece, each column supporting a respective third electrical connector.

16. The assembly of claim 12, further comprising a second busbar having a second top surface extending entirely in a third plane and a second bottom surface extending entirely in a fourth plane and a plurality of third electrical components each having a third electrical connector, and wherein the interface piece includes a fourth portion supporting the second busbar and a base supporting the plurality of third electrical components, wherein the base maintains each third connector of the plurality of third electrical components at the same third vertical position relative to the second busbar.

17. The assembly of claim 16, wherein each third electrical connector is electrically coupled to the second busbar and each third electrical component is positioned vertically below the second busbar.

18. The assembly of claim 17, wherein the second busbar is located at a first height relative to the base of the interface piece and the first busbar is located at a second height relative to the base of the interface piece, the second height larger than the first height.

19. The assembly of claim 12, wherein the assembly is configured to be housed in a housing of the PDU.

20. The assembly of claim 12, wherein the interface piece is comprised of plastic.
